(19) United States
(12) Patent Application Publication
(10) Pub. No.: US 2025/0098426 A1
(43) Pub. Date: Mar. 20, 2025

(54) DISPLAY PANEL, METHOD FOR DRIVING SAME, AND DISPLAY DEVICE

(71) Applicants: Beijing BOE Technology Development Co., Ltd., Beijing (CN); BOE Technology Group Co., Ltd., Beijing (CN)

(72) Inventors: Renrong GAI, Beijing (CN); Jing WANG, Beijing (CN); Shantao CHEN, Beijing (CN); Jing YANG, Beijing (CN); Hao ZHANG, Beijing (CN); Yonghui LIU, Beijing (CN); Zibo NI, Beijing (CN)

(21) Appl. No.: 18/576,715

(22) PCT Filed: Apr. 13, 2023
(86) PCT No.: PCT/CN2023/088151

§ 371 Date: Jan. 4, 2024

(51) Int. Cl. H10K 59/122; G06F 3/044; H10K 59/121; H10K 59/131; H10K 59/80; H10K 59/88

(52) U.S. Cl. CPC H10K 59/122; G06F 3/0446; H10K 59/1213; H10K 59/131; H10K 59/8792; H10K 59/88

(57) ABSTRACT

Provided is a display panel, including a driver backplane, a pixel definition layer, a plurality of light-emitting devices, and a touch line. A plurality of openings are formed in the pixel definition layer. The light-emitting device includes a normal element and at least one privacy element, which are disposed in different openings. The touch line includes a first wiring and a second wiring. An orthographic projection of the first wiring on the driver backplane falls on a periphery of an orthographic projection of the opening, where the privacy element is disposed, on the driver backplane. A distance between an orthographic projection of the second wiring on the driver backplane and the orthographic projection of the opening on the driver backplane is greater than a distance between the orthographic projection of the first wiring on the driver backplane and the orthographic projection of the opening on the driver backplane.

### CROSS-REFERENCE TO RELATED APPLICATION

The present disclosure is a U.S. national stage of international application No. PCT/CN2023/088151, filed on Apr. 13, 2023, the content of which is herein incorporated by reference in its entirety.

### TECHNICAL FIELD

The present disclosure relates to the field of display technologies, and in particular, relates to a display panel, a method for driving the same, and a display device.

### BACKGROUND

Organic light-emitting diode (OLED) displays have aroused widespread concern for their advantages of self-luminescence, low power consumption, thinness, flexibility, vivid colors, high contrast, and fast response rate.

### SUMMARY

According to some embodiments of the present disclosure, a display panel is provided. The display panel includes a driver backplane, a pixel definition layer, a plurality of light-emitting devices, and a touch line; wherein
the pixel definition layer is disposed on a side of the driver backplane, and a plurality of openings are formed in the pixel definition layer;
each of the light-emitting devices includes a normal element and at least one privacy element, wherein the privacy element and the normal element are respectively disposed in different openings of the plurality of openings;
the touch line is disposed on a side, away from the driver backplane, of the light-emitting device;
the touch line includes a first wiring and a second wiring, wherein an orthographic projection of the first wiring on the driver backplane falls on a periphery of an orthographic projection of an opening, where the privacy element is disposed, on the driver backplane;
a distance between an orthographic projection of the second wiring on the driver backplane and the orthographic projection of the opening, where the privacy element is disposed, on the driver backplane is greater than a distance between the orthographic projection of the first wiring on the driver backplane and the orthographic projection of the opening, where the privacy element is disposed, on the driver backplane; and
a line width of at least a partial region of the first wiring is greater than a line width of the second wiring.

In some embodiments, the orthographic projection of the first wiring on the driver backplane forms a continuous closed shape.

In some embodiments, the orthographic projection of the first wiring on the driver backplane is discontinuous in a region between orthographic projections of some of the privacy elements and the normal elements adjacent to each other on the driver backplane; and
the display panel further includes a dummy wiring disposed on the side, away from the driver backplane, of the light-emitting device; wherein an orthographic projection of the dummy wiring on the driver backplane falls between the orthographic projections of some of the privacy elements and the normal elements adjacent to each other on the driver backplane, and the orthographic projection of the dummy wiring on the driver backplane falls in a discontinuity region of the orthographic projection of the first wiring on the driver backplane;
a distance between the orthographic projection of the dummy wiring on the driver backplane and the orthographic projection of the opening, where the privacy element is disposed, on the driver backplane is less than the distance between the orthographic projection of the second wiring on the driver backplane and the orthographic projection of the opening, where the privacy element is disposed, on the driver backplane;
a line width of the dummy wiring is greater than the line width of the second wiring; and
the dummy wiring and the first wiring are insulated from each other, and the orthographic projections of the dummy wiring and the first wiring on the driver backplane form a continuous closed shape.

In some embodiments, the privacy element includes a first anode, a first light-emitting functional layer, and a first cathode; and
the normal element includes a second anode, a second light-emitting functional layer, and a second cathode; wherein
the first anode, the first light-emitting functional layer, and the first cathode are successively stacked along a direction away from the driver backplane;
the second anode, the second light-emitting functional layer, and the second cathode are successively stacked along the direction away from the driver backplane;
the orthographic projections of the first wiring and the dummy wiring on the driver backplane are not overlapped with an orthographic projection of the second light-emitting functional layer on the driver backplane.

In some embodiments, the orthographic projections of the first wiring and the dummy wiring on the driver backplane are overlapped with peripheral edges of an orthographic projection of the first light-emitting functional layer on the driver backplane.

In some embodiments, the orthographic projections of the first wiring and the dummy wiring on the driver backplane are not overlapped with an orthographic projection of the first light-emitting functional layer on the driver backplane.

In some embodiments, the privacy element is adjacent to the normal element, and
equations for calculating a width M of the first wiring or the dummy wiring line disposed between the privacy element and the normal that are adjacent to each other are as follows: M=C+x−y;

x=B−A−z; and

y=(A+z)/tan(90°−θ/2)−B; wherein
A represents a distance between a surface of a side, close to the privacy element, of the first wiring or the dummy wiring and a surface of a side, away from the driver backplane, of the privacy element;
B represents a sectional width, on a first section perpendicular to the driver backplane, of the opening where the privacy element is disposed, wherein the first section is parallel to an arrangement direction of the privacy element and the normal element;
C represents a sectional width, on the first section, of the pixel definition layer disposed between the privacy element and the normal element adjacent to each other, wherein the sectional width of the pixel definition layer refers to a sectional width of the pixel definition layer at a position flush with the surface of the side, away from the driver backplane, of the privacy element;
x represents a distance, on the first section, between an edge of an end, close to the privacy element, of the first wiring or the dummy wiring and an edge of an end, close to the first wiring or the dummy wiring, of the first light-emitting feature layer;
y represents a distance, on the first section, between an edge of an end, away from the privacy element, of the first wiring or the dummy wiring and an edge of an end, close to the first wiring or the dummy wiring, of the second light-emitting functional layer;
z represents a thickness of the first wiring or the dummy wiring; and
θ represents a viewing angle of the normal element on the first section.

In some embodiments, two of the privacy elements are adjacent to each other, and the adjacent two privacy elements are respectively a first privacy element and a second privacy element; and
equations for calculating a line width N of the first wiring disposed between the first privacy element and the second privacy element and close to an opening where the first privacy element is disposed are as follows: N=C+x−y;

x=B−A−z; and

y=(A+z)/tan(90°−α/2)−B; wherein
A represents a distance between a surface of a side, close to the first privacy element, of the first wiring and a surface of a side, away from the driver backplane, of the first privacy element;
B represents a sectional width, on a second section perpendicular to the driver backplane, of the opening where the first privacy element is disposed, wherein the second section is parallel to an arrangement direction of the first privacy element and the second privacy element;
C represents a sectional width, on the second section, of the pixel definition layer disposed between the first privacy element and the second privacy element adjacent to each other, wherein the sectional width of the pixel definition layer refers to a sectional width of the pixel definition layer at a position flush with the surface of the side, away from the driver backplane, of the first privacy element;
x represents a distance, on the second section, between an edge of an end, close to the first privacy element, of the first wiring and an edge of an end, close to the first wiring, of the first light-emitting feature layer of the first privacy element;
y represents a distance, on the second section, between an edge of an end, away from the first privacy element, of the first wiring and an edge of an end, close to the first wiring, of the first light-emitting functional layer of the second privacy element;
z represents a thickness of the first wiring; and
α represents a viewing angle of the second privacy element on the second section.

In some embodiments, the privacy element is adjacent to the normal element; and
equations for calculating a width M of the first wiring or the dummy wiring disposed between the privacy element and the normal element adjacent to each other are as follows: M=C−x−y;

x=A+z−B; and

y=(A+z)/tan(90°−θ/2)−B; wherein
A represents a distance between a surface of a side, close to the privacy element, of the first wiring or the dummy wiring and a surface of a side, away from the driver backplane, of the privacy element;
B represents a sectional width, on a first section perpendicular to the driver backplane, of the opening where the privacy element is disposed, wherein the first section is parallel to an arrangement direction of the privacy element and the normal element;
C represents a sectional width, on the first section, of the pixel definition layer disposed between the privacy element and the normal element adjacent to each other, wherein the sectional width of the pixel definition layer refers to a sectional width of the pixel definition layer at a position flush with the surface of the side, away from the driver backplane, of the privacy element;
x represents a distance, on the first section, between an edge of an end, close to the privacy element, of the first wiring or the dummy wiring and an edge of an end, close to the first wiring or the dummy wiring, of the first light-emitting feature layer;
y represents a distance, on the first section, between an edge of an end, away from the privacy element, of the first wiring or the dummy wiring and an edge of an end, close to the first wiring or the dummy wiring, of the second light-emitting functional layer;
z represents a thickness of the first wiring or the dummy wiring; and
θ represents a viewing angle of the normal element on the first section.

In some embodiments, two of the privacy elements are adjacent to each other, and the adjacent two privacy elements are respectively a first privacy element and a second privacy element; and
equations calculating a line width N of the first wiring disposed between the first privacy element and the second privacy element and close to an opening where the first privacy element is disposed are as follows: N=C−x−y;

x=A+z−B; and

y=(A+z)/tan(90°−α/2)−B; wherein
A represents a distance between a surface of a side, close to the first privacy element, of the first wiring and a surface of a side, away from the driver backplane, of the first privacy element;
B represents a sectional width, on a second section perpendicular to the driver backplane, of the opening where the first privacy element is disposed, wherein the second section is parallel to an arrangement direction of the first privacy element and the second privacy element;
C represents a sectional width, on the second section, of the pixel definition layer disposed between the first privacy element and the second privacy element adjacent to each other, wherein the sectional width of the pixel definition layer refers to a sectional width of the pixel definition layer at a position flush with the surface of the side, away from the driver backplane, of the first privacy element;
x represents a distance, on the second section, between an edge of an end, close to the first privacy element, of the first wiring and an edge of an end, close to the first wiring, of the first light-emitting feature layer of the first privacy element;
y represents a distance, on the second section, between an edge of an end, away from the first privacy element, of the first wiring and an edge of an end, close to the first wiring, of the first light-emitting functional layer of the second privacy element;
z represents a thickness of the first wiring; and
α represents a viewing angle of the second privacy element on the second section.

In some embodiments, θ ranges from 120° to 160°.

In some embodiments, α ranges from 40° to 100°.

In some embodiments, the display panel further includes a package layer and a light-shielding layer; wherein
the package layer is disposed on the side, away from the driver backplane, of the light-emitting device and on a side, close to the driver backplane, of the touch line and the dummy wiring, and the package layer is configured to package the light-emitting device;
the light-shielding layer is disposed on a side, away from the driver backplane, of the touch line and the dummy wiring; or
the light-shielding layer is disposed on the side, close to the driver backplane, of the touch line and the dummy wiring and on a side, away from the driver backplane, of the package layer; or
the light-shielding layer is disposed on a side, close to the driver backplane, of the package layer and on the side, away from the driver backplane, of the light-emitting device; and
an orthographic projection of the light-shielding layer on the driver backplane at least covers the orthographic projection of the first wiring on the driver backplane disposed between the orthographic projections of the adjacent privacy elements on the driver backplane and the orthographic projection of the first wiring or the dummy wiring on the driver backplane disposed between the orthographic projections of the adjacent privacy element and the normal element on the driver backplane.

In some embodiments, the light-shielding layer is made of a black organic material.

In some embodiments, the display panel further includes a plurality of data lines; wherein
the plurality of light-emitting devices are arranged in an array;
each column of the light-emitting devices is connected to one of the data lines; and
in the light-emitting devices, the privacy elements and the normal elements are arranged along a column direction of the array, and the privacy elements and the normal elements are electrically connected to the same data line of the plurality of data lines.

In some embodiments, in the array of light-emitting devices, odd rows are the privacy elements, and even rows are the normal elements; or
in the array of light-emitting devices, odd rows are the normal elements, and even rows are the privacy elements; and
the privacy elements and the normal elements are successively alternately arranged along the column direction of the array.

In some embodiments, the plurality of light-emitting devices include a plurality of red light-emitting devices, a plurality of green light-emitting devices, and a plurality of blue light-emitting devices; wherein
each of the red light-emitting devices includes a red privacy element and a red normal element;
each of the green light-emitting devices includes a green privacy element and a green normal element; and
each of the blue light-emitting devices includes a blue privacy element and a blue normal element;
wherein a slope angle of a portion of the pixel definition layer, wherein an opening, where the green privacy element is disposed, is formed in the portion is greater than a slope angle of a portion of the pixel definition layer, wherein an opening, where the red privacy element is disposed, is formed in the portion, and the slope angle of the portion of the pixel definition layer, wherein the opening, where the red privacy element is disposed, is formed in the portion is greater than a slope angle of a portion of the pixel definition layer, wherein an opening, where the blue privacy element is disposed, is formed in the portion.

In some embodiments, portions of the pixel definition layer have a same slope angle, wherein openings, where the red normal element, the green normal element, and the blue normal element respectively are disposed, are respectively formed in the portions.

In some embodiments, the driver backplane includes a plurality of pixel circuits; wherein each of the light-emitting devices is electrically connected to one of the pixel circuits; and
each of the pixel circuits includes a driver transistor, wherein the driver transistor is electrically connected to the normal element and the privacy element of one of the light-emitting devices.

According to some embodiments of the present disclosure, a display device is provided. The display device includes the display panel as described above.

According to some embodiments of the present disclosure, a method for driving a display panel is provided. The method includes: driving a normal element and a privacy element of a light-emitting device to emit light by a driver backplane in a case where the display panel is in a normal state; or
driving the privacy element of the light-emitting device to emit light by the driver backplane in a case where the display panel is in a privacy state.

### BRIEF DESCRIPTION OF DRAWINGS

For clearer descriptions of the technical solutions in the embodiments of the present disclosure, the following briefly introduces the accompanying drawings to be required in the descriptions of the embodiments. Apparently, the accompanying drawings in the following description show merely some embodiments of the present disclosure, and persons of ordinary skills in the art may still derive other drawings from these accompanying drawings without creative efforts.

FIG. 1 is a schematic diagram of a sharing state and a privacy state when a display product is displayed in some practices.

FIG. 2a is a top-view schematic structural diagram of a display panel according to some embodiments of the present disclosure.

FIG. 2b is a top-view schematic structural diagram of another display panel according to some embodiments of the present disclosure.

FIG. 2c is a sectional schematic structural diagram along a section line AA in FIG. 2a.

FIG. 2d is a sectional schematic structural diagram along a section line BB in FIG. 2b.

FIG. 2e is a sectional schematic structural diagram along a section line CC in FIG. 2a.

FIG. 2f is a sectional schematic structural diagram along a section line DD in FIG. 2b.

FIG. 2g is a schematic diagram of a range of light-emitting angles of a normal element and a privacy element according to some embodiments of the present disclosure.

FIG. 2h is another sectional schematic structural diagram along a section line AA in FIG. 2a.

FIG. 3a is a schematic diagram of an arrangement of touch lines on a display panel according to some embodiments of the present disclosure.

FIG. 3b is a partial sectional schematic structural diagram along a section line EE in FIG. 3a.

FIG. 3c is a top view of a microscopic enlarged diagram of touch lines according to some embodiments of the present disclosure.

### DETAILED DESCRIPTION

For a better understanding of the technical solutions of the embodiments of the present disclosure by those skilled in the art, a display panel, a method for driving the same, and a display device according to the present disclosure are described in further detail hereinafter with reference to the accompanying drawings.

The embodiments of the present disclosure will be described in further detail hereinafter with reference to the accompanying drawings, but the illustrated embodiments may be embodied in different forms and should not be construed as being limited to the embodiments elaborated in the present disclosure. Instead, these embodiments are provided for the purpose of making the present disclosure thorough and complete and will enable those skilled in the art to fully understand the scope of the present disclosure.

The embodiments of the present disclosure are not limited to the embodiments illustrated in the accompanying drawings, but rather include modifications to configurations based on manufacturing processes. Accordingly, the regions exemplified in the accompanying drawings are schematic, and the shapes of the regions shown in the drawings exemplify specific shapes of the regions, but are not intended to be limiting.

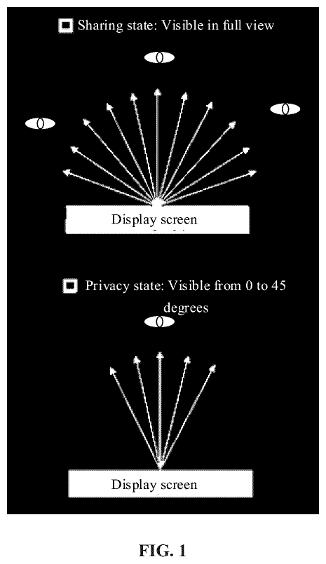

In some practices, as shown in FIG. 1, which is a schematic diagram illustrating a sharing state and a privacy state of a display product when displaying data or images, with the increasing applications of display products, there is a desire for people to share information with others, but in some specific situations, privacy is desired. For instance, when dealing with confidential data, the information is easily visible to others nearby. Similarly, when entering personal information on a mobile phone, the information may be easily seen by others. Therefore, switching of a display device between the sharing state and the privacy state during display has gradually become a demand trend for display products.

Based on the demand for switching between the sharing and privacy states during the display of display products, in some practices, an externally attached privacy film on a display screen is used. When privacy is needed, the privacy film is manually attached in front of the display screen, and when not required, the privacy film is manually removed. Additionally, in some practices a liquid crystal layer is placed on a display side of the display screen, such that light exiting angles of the display screen are restricted through the liquid crystal orientation of the liquid crystal layer.

The manual attachment of the privacy film is inconvenient, which fails to achieve flexible and convenient switching between the sharing and privacy states. Similarly, the method of placing the liquid crystal layer on the display side of the display screen increases a thickness of the screen, and thus the user's demands are not adequately satisfied.

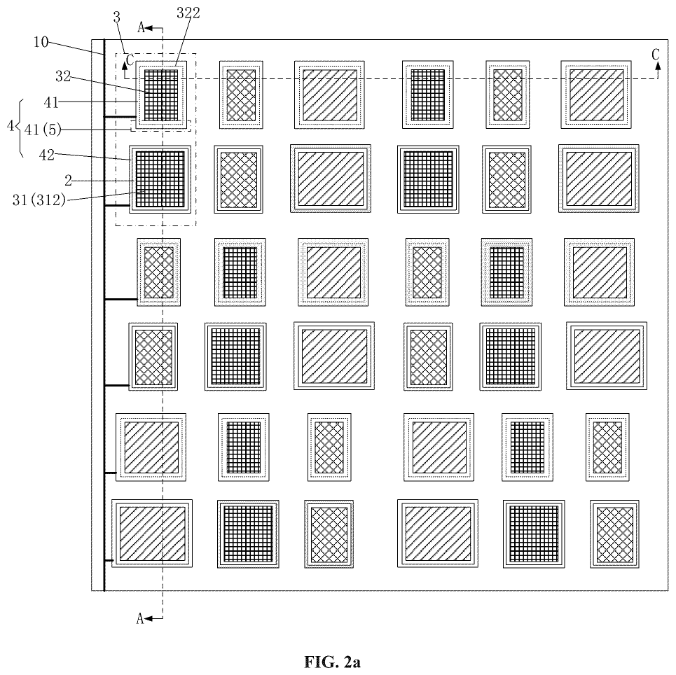

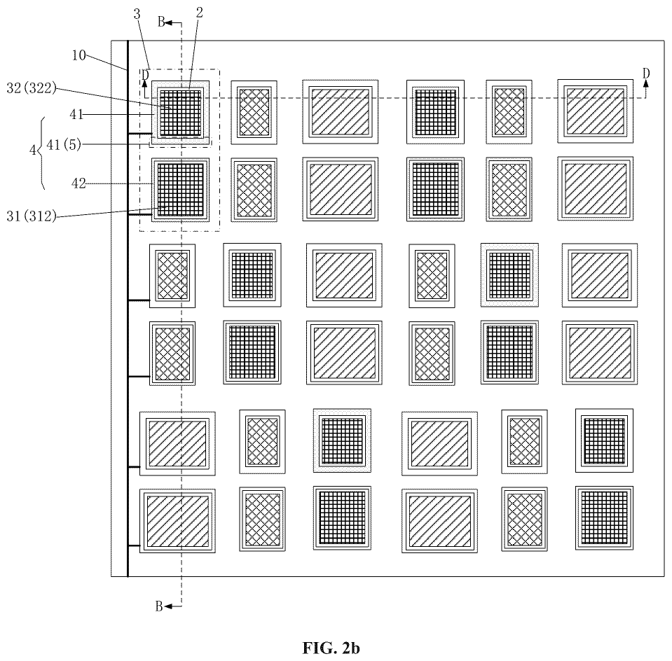

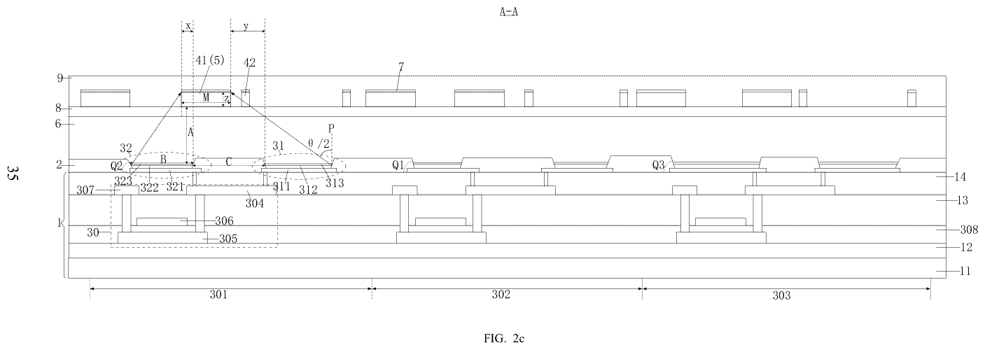

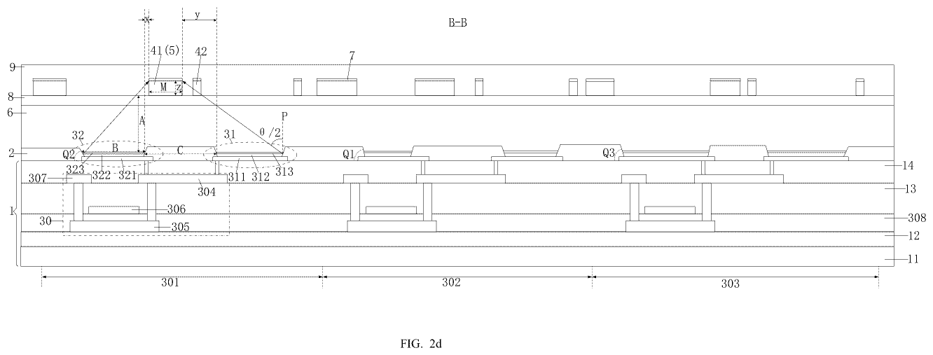

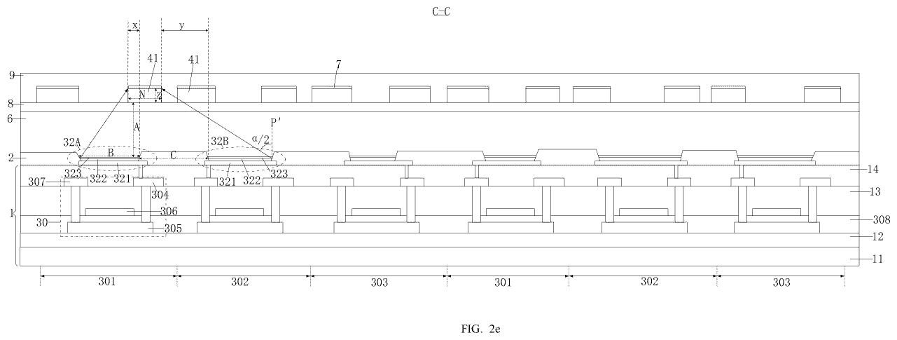

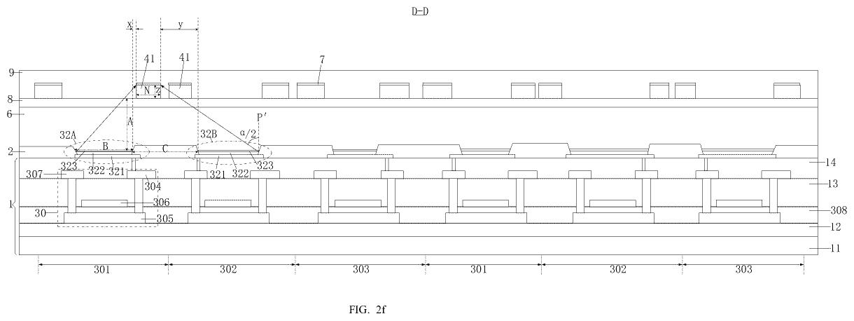

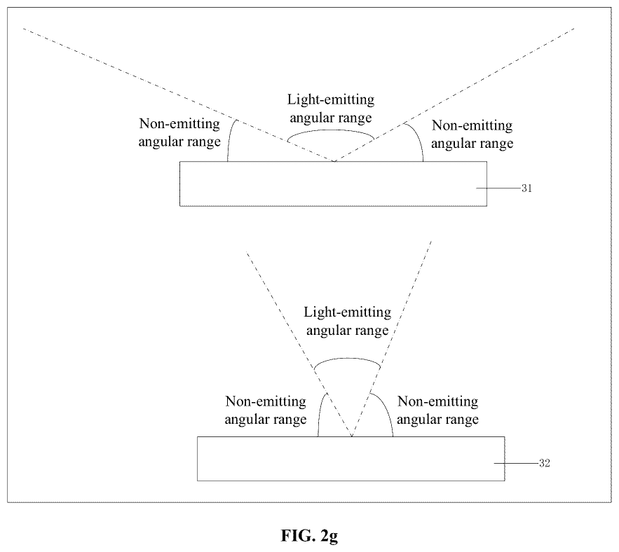

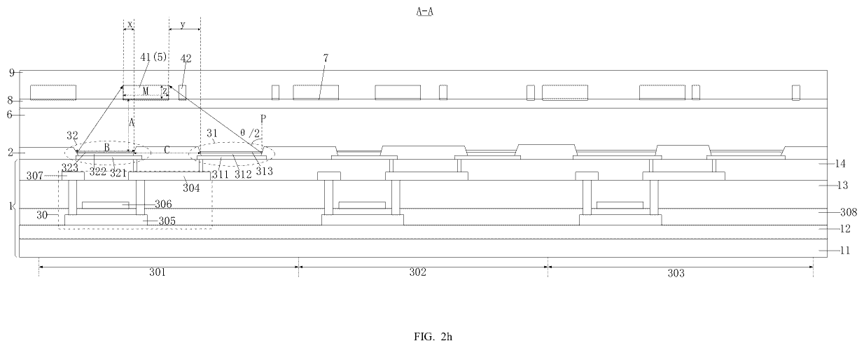

To address the problem in some practices that the switching between the sharing state and the privacy state of a display product is not convenient and quick, some embodiments of the present disclosure provide a display panel. FIG. 2a is a top-view schematic structural diagram of a display panel according to some embodiments of the present disclosure. FIG. 2b is a top-view schematic structural diagram of another display panel according to some embodiments of the present disclosure. FIG. 2c is a sectional schematic structural diagram along a section line AA in FIG. 2a. FIG. 2d is a sectional schematic structural diagram along a section line BB in FIG. 2b. FIG. 2e is a sectional schematic structural diagram along a section line CC in FIG. 2a. FIG. 2f is a sectional schematic structural diagram along a section line DD in FIG. 2b. Referring to FIG. 2a, FIG. 2b, FIG. 2c, FIG. 2d, FIG. 2e, and FIG. 2f, the display panel includes a driver backplane 1, a pixel definition layer 2, a plurality of light-emitting devices 3, and a touching line 4. The pixel definition layer 2 is disposed at a side of the driver backplane 1, and a plurality of openings are formed in the pixel definition layer 2. The light-emitting device 3 includes a normal element 31 and at least one privacy element 32, and the privacy element 32 and the normal element 31 are disposed in different openings. The touch line 4 is disposed on a side, away from the driver backplane 1, of the light-emitting device 3, and the touch line 4 includes a first wiring 41 and a second wiring 42. An orthographic projection of the first wiring 41 on the driver backplane 1 falls on a periphery of an orthographic projection of an opening, where the privacy element 32 is disposed, on the driver backplane 1. A distance between an orthographic projection of the second wiring line 42 on the driver backplane 1 and the orthographic projection of the opening on the driver backplane 1 where the privacy element 32 is disposed is greater than a distance between the orthographic projection of the first wiring line 41 on the driver backplane 1 and the orthographic projection of the opening on the driver backplane 1 where the privacy element 32 is disposed. A line width of at least a partial region of the first wiring line 41 is greater than a line width of the second wiring 42.

The orthographic projection of the first wiring 41 on the driver backplane 1 is nearest the orthographic projection of the opening on the driver backplane 1 where the privacy element 32 is disposed. In some embodiments, a line width of the entire first wiring 41 is greater than the line width of the second wiring 42.

FIG. 2g is a schematic diagram of a range of light-emitting angles of a normal element and a privacy element according to some embodiments of the present disclosure. In some embodiments, referring to FIG. 2g, the normal element 31 refers to an element whose an angular range of light emitted from a light-emitting surface ranges from 120° to 160°. That is, assuming that the light-emitting surface of the normal element 31, which is a flat surface, emits light of 120°, the normal element 31 emits light within an angular range from 30° to 150° with respect to its light-emitting surface. The privacy element 32 refers to an element whose angular range of light emitted from a light-emitting surface ranges from 40° to 50°. That is, assuming that the light-emitting surface of the privacy element 32, which is a flat surface, emits light of 30°, the privacy element 32 emits light within an angular range from 75° to 105° with respect to its light-emitting surface.

In some embodiments, both the normal element 31 and the privacy element 32 are organic light-emitting diode (OLED) devices.

In some embodiments, referring to FIG. 2a, FIG. 2b, and FIG. 2c, a light-emitting device 3 is split into two parts, that is, a normal element 31 and a privacy element 32. The privacy element 32 includes a first anode 321, a first light-emitting functional layer 322, and a first cathode 323. The first anode 321, the first light-emitting functional layer 322, and the first cathode 323 are successively stacked along a direction away from the driver backplane 1. The normal element 31 includes a second anode 311, a second light-emitting functional layer 312, and a second cathode 313. The second anode 311, the second light-emitting functional layer 312, and the second cathode 313 are successively stacked along the direction away from the driver backplane 1.

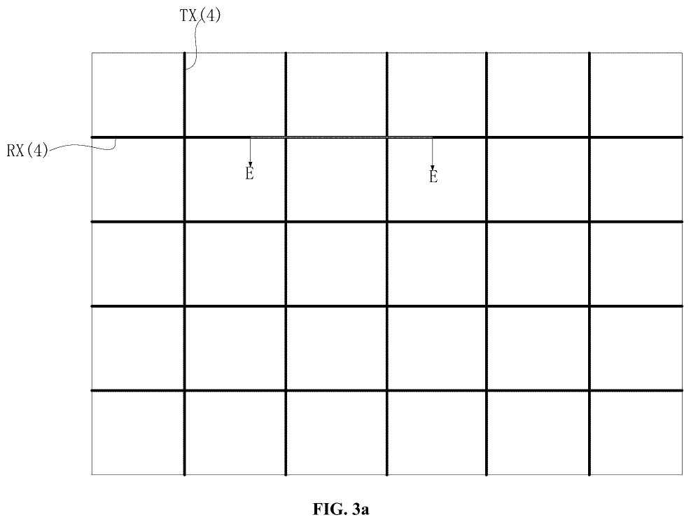

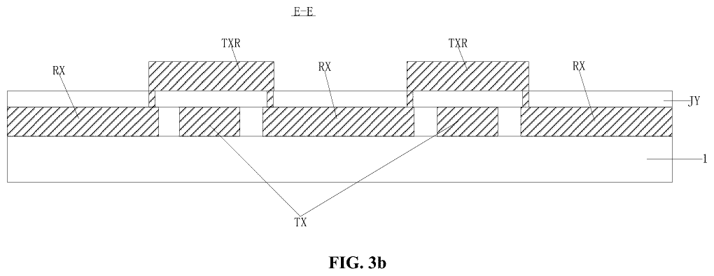

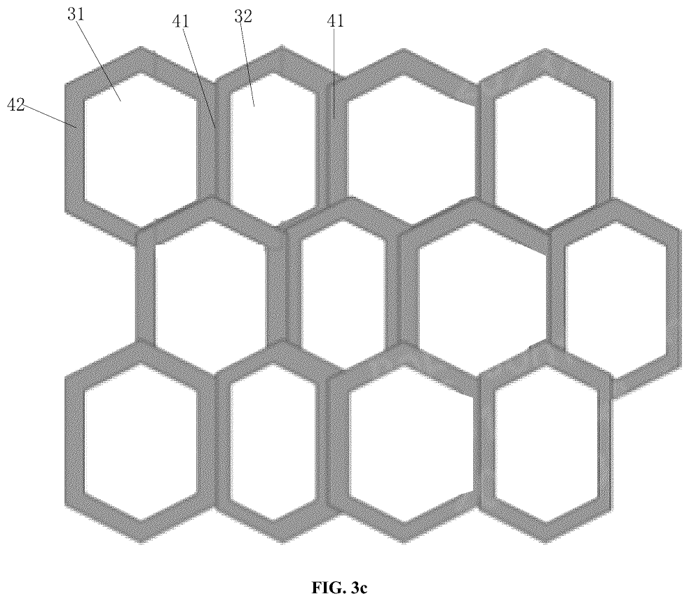

FIG. 3a is a schematic diagram of an arrangement of touch lines on a display panel according to some embodiments of the present disclosure. In some embodiments, referring to FIG. 3a, the touch lines 4 include longitudinal touch driver wirings TX and transversal touch sense wirings RX. The longitudinal touch driver wirings TX and the transversal touch sense wirings RX are spatially intersected with each other, forming mutual capacitances at points of spatial intersection. The touch control of the display panel is achieved by detecting mutual capacitance values between the touch driver wirings TX and the touch sense wirings RX.

FIG. 3b is a partial sectional schematic structural diagram along a section line EE in FIG. 3a. In some embodiments, referring to FIG. 3b, the touch line 4 further includes a bridge portion TXR disposed at the intersection position of the touch driver wiring TX and the touch sense wiring RX. The touch driver wiring TX and the touch sense wiring RX are disposed in the same layer, and the bridge portion TXR is disposed on a side, away from or close to the driver backplane, of the touch driver wiring TX and the touch sense wiring RX. An insulation layer JY is disposed between the bridge portion TXR and both the touch driver wiring TX and the touch sense wiring RX. The bridge portion TXR is connected, via two holes formed in the insulation layer JY, to two discontinuity ends of the touch sense wiring RX that are discontinuous at the intersection position. In this way, the spatial intersection of the touch driver wirings TX and the touch sense wirings RX is achieved.

FIG. 3c is a top view of a microscopic enlarged diagram of touch lines according to some embodiments of the present disclosure. In some embodiments, referring to FIG. 3c, the microscopic shapes of the touch driver wiring TX, the touch sense wiring RX, and the bridge portion TXR are grid-shaped. The first wiring 41 is a single wiring of the touch driver wiring TX, the touch sense wiring RX, and the bridge portion TXR whose orthographic projection the driver backplane 1 is closest to the opening where the privacy element 32 is disposed. The second wirings 42 are other grid-like wirings of the touch driver wiring TX, the touch sense wiring RX, and the bridge portion TXR whose orthographic projection on the driver backplane 1 is farther away from the opening where the privacy element 32 is disposed than the first wiring 41.

In some embodiments, referring to FIG. 3c, the orthographic projection of the first wiring 41 on the driver backplane 1 forms a continuous closed shape. This continuous closed shape refers to the fact that portions of the orthographic projections, closest to the opening where the privacy element 32 is disposed, of the touch driver wiring TX and/or the touch sense wiring RX and/or the bridge portion TXR on the driver backplane 1 are spliced together to form a continuous closed shape. That is, the first wiring 41 is in the continuous closed shape formed solely by the portion of the orthographic projection, closest to the opening where the privacy element 32 is disposed, of the touch driver wiring TX or the touch sense wiring RX or the bridge portion TXR on the driver backplane 1. Alternatively, the first wiring 41 is in the continuous closed shape formed by splicing the portions of the orthographic projections, closest to the opening where the privacy element 32 is disposed, of the touch driver wiring TX, the touch sense wiring RX, and the bridge portion TXR on the driver backplane 1.

In some embodiments, the line width of the first wiring line 41 is greater than the line width of the second wiring line 42. The second wiring line 42 is arranged as the touch line 4 in a spacing region between the openings of the light-emitting device 3. The first wiring line 41, in one aspect, serves as the touch line 4 and exerts the touch control function of the touch line 4, and in one aspect, is configured to form a shield for light-exiting regions at peripheral edges of the opening where the privacy element 32 is disposed, such that an area of the light-exiting region of the opening where the privacy element 32 is disposed is reduced, and thus a viewing angle of the privacy element 32 is restricted to a preset privacy viewing angle range, and the privacy display of the display panel in some privacy scenarios is achieved.

In some embodiments, referring to FIG. 2a and FIG. 2b, the orthographic projection of the first wiring 41 on the driver backplane 1 is discontinuous in a region between orthographic projections on the driver backplane 1 of some of the adjacent privacy elements 32 and the normal elements 31. The display panel further includes a dummy wiring 5 disposed on the side, away from the driver backplane 1, of the light-emitting device 3. An orthographic projection of the dummy wiring 5 on the driver backplane 1 is disposed between the orthographic projections of some of the privacy elements 32 and the normal elements 31 adjacent to each other on the driver backplane 1. The orthographic projection of the dummy wiring 5 on the driver backplane 1 falls in a discontinuity region of the orthographic projection of the first wiring 41 on the driver backplane 1. A distance between the orthographic projection of the dummy wiring 5 on the driver backplane 1 and the orthographic projection of the opening on the driver backplane 1 where the privacy element 32 is disposed is less than a distance between the orthographic projection of the second wiring 42 on the driver backplane 1 and the orthographic projection of the opening on the driver backplane 1 where the privacy element 32 is disposed. A line width of the dummy wiring 5 is greater than the line width of the second wiring 42. The dummy wiring 5 and the first wiring 41 are insulated from each other. The orthographic projections of the dummy wiring 5 and the first wiring 41 on the driver backplane 1 form a continuous closed shape.

The region between the orthographic projections on the driver backplane 1 of the privacy element 32 and the normal element 31 that are split by one light-emitting device 3 is not provided with the touch line 4, therefore, by providing the dummy wiring 5 in the region where the touch line 4 is not provided, and by forming the continuous closed shape by the orthographic projections of the dummy wiring 5 and the first wiring 41 on the driver backplane 1, the light-exiting region of the peripheral edges of the opening where the privacy element 32 is disposed is shielded. In this way, the area of the light-exiting region of the opening where the privacy element 32 is disposed is reduced, such that the viewing angle of the privacy element 32 is restricted to the preset privacy viewing angle range, and thus the privacy display of the display panel in some privacy scenarios is achieved.

In some embodiments, the dummy wiring 5 is overhanging, and the dummy wiring 5 and the first wiring 41 are respectively disposed in different layers, such that the dummy wiring 5 and the first wiring 41 are mutually insulated.

In some embodiments, both the touch line 4 and the dummy wiring 5 are made of a conductive material that shields light, such as copper, aluminum, silver, copper-silver alloy, or other light-shielding metals or metal alloys, or indium-tin-oxide/silver/indium-tin-oxide, or other light-shielding conductive stacked materials.

In some embodiments, referring to FIG. 2a, FIG. 2b, FIG. 2c, and FIG. 2d, the orthographic projections of the first wiring 41 and the dummy wiring 5 on the driver backplane 1 are not overlapped with an orthographic projection of the second light-emitting functional layer 312 on the driver backplane 1.

In some embodiments, referring to FIG. 2a, FIG. 2b, FIG. 2c, and FIG. 2d, the orthographic projection of the first wiring 41 on the driver backplane 1 is not overlapped with the orthographic projection of the second light-emitting functional layer 312 on the driver backplane 1.

In some embodiments, referring to FIG. 2a, the orthographic projection of the first wiring 41 on the driver backplane 1 is overlapped with peripheral edges of an orthographic projection of the first light-emitting functional layer 322 on the driver backplane 1.

In some embodiments, referring to FIG. 2a, the orthographic projections of the first wiring 41 and the dummy wiring 5 on the driver backplane 1 are overlapped the peripheral edges of the orthographic projection of the first light-emitting functional layer 322 on the driver backplane 1.

In some embodiments, referring to FIG. 2c, the privacy element 32 is adjacent to the normal element 31, and equations formula for calculating a line width M of the first wiring 41 or the dummy wiring 5 disposed between the adjacent privacy element 32 and the normal element 31 are as follows. M=C+x−y; x=B−A−z; and y=(A+z)/tan(90°−θ/2)−B. A represents a distance between a surface on a side, close to the privacy element 32, of the first wiring 41 or dummy wiring 5 and a surface on a side, away from the driver backplane 1, of the privacy element 32. B represents a sectional width, on a first section perpendicular to the driver backplane 1, of the opening where the privacy element 32 is disposed. The first section is parallel to an arrangement direction of the privacy element 32 and the normal element 31. C represents a sectional width, on the first section, of a pixel definition layer 2 disposed between the adjacent privacy element 32 and the normal element 31. The sectional width of the pixel definition layer 2 is a sectional width of the pixel definition layer 2 at a position flush with the surface on the side, away from the driver backplane 1, of the privacy element 32. x represents a distance, on the first section, between an edge of an end, close to the privacy element 32, of the first wiring 41 or dummy wiring 5 and an edge of an end, close to the first wiring 41 or dummy wiring 5, of the first light-emitting functional layer 322. y represents a distance, on the first section, between an edge of an end, away from the privacy element 32, of the first wiring 41 or dummy wiring 5 and an edge of an end, close to the first wiring 41 or dummy wiring 5, of the second light-emitting functional layer 312. z represents a thickness of the first wiring 41 or dummy wiring 5. θ represents a viewing angle of the normal element 31 on the first section.

θ/2 represents an included angle, on the first section, between the outermost light emitted from the normal element 31 and a normal line P perpendicular to the light-emitting surface of the normal element 31.

In some embodiments, referring to FIG. 2e, two privacy elements 32 are adjacent to each other. The adjacent two privacy elements 32 are respectively a first privacy element 32A and a second privacy element 32B. Equations for calculating a linewidth N of the first wiring 41 which is disposed between the first privacy element 32A and the second privacy element 32B and close to an opening where the first privacy element 32A is disposed are as follows. N=C+x−y; x=B−A−z; and y=(A+z)/tan(90°−α/2)−B. A represents a distance between a surface on a side, close to the first privacy element 32A, of the first wiring 41 and a surface on a side, away from the driver backplane 1, of the first privacy element 32A. B represents a sectional width, on a second section perpendicular to the driver backplane 1, of the opening where the first privacy element 32A is disposed. The second section is parallel to an arrangement direction of the first privacy element 32A and the second privacy element 32B. C represents a sectional width, on the second section, of a pixel definition layer 2 disposed between the adjacent first privacy element 32A and the second privacy element 32B. The sectional width of the pixel definition layer 2 is a sectional width of the pixel definition layer 2 at a position flush with the surface on the side, away from the driver backplane 1, of the first privacy element 32A. x represents a distance, on the second section, between an edge of an end, close to the first privacy element 32A, of the first wiring 41 and an edge of an end, close to the first wiring 41, of the first light-emitting functional layer 322 of the first privacy element 32A. y represents a distance, on the second section, between an edge of an end, away from the first privacy element 32A, of the first wiring 41 and an edge of an end, close to the first wiring 41, of the first light-emitting functional layer 312 of the second privacy element 32B. z represents a thickness of the first wiring 41. α represents a viewing angle of the second privacy element 32B on the second section.
α/2 represents an included angle, on the second section, between the outermost light emitted from the second privacy element 32B and a normal line P′ perpendicular to a light-emitting surface of the second privacy element 32B.

In some embodiments, the structural arrangement of the first wiring 41 and the dummy wiring 5 in FIG. 2a and the method of calculating the line widths of the first wiring 41 and the dummy wiring 5 in FIG. 2c and FIG. 2e apply to achieving the privacy display of a medium-to-large-sized display panel, such as a display panel of 10 to 16 inches or more than 16 inches, or a display panel with a resolution of more than 400 PPI.

In some embodiments, referring to FIG. 2b and FIG. 2d, the orthographic projection of the first wiring 41 on the driver backplane 1 is not overlapped with the orthographic projection of the first light-emitting functional layer 322 on the driver backplane 1.

In some embodiments, referring to FIG. 2b and FIG. 2d, the orthographic projections of the first wiring 41 and the dummy wiring 5 on the driver backplane 1 are not overlapped with the orthographic projection of the first light-emitting functional layer 322 on the driver backplane 1.

In some embodiments, referring to FIG. 2d, the privacy element 32 is adjacent to the normal element 31, and equations for calculating a line width M of the first wiring 41 or the dummy wiring 5 disposed between the adjacent privacy element 32 and the normal element 31 are as follows. M=C−x−y; x=A+z−B; and y=(A+z)/tan(90°−θ/2)−B. A represents a distance between a surface on a side, close to the privacy element 32, of the first wiring 41 or dummy wiring 5 and a surface on a side, away from the driver backplane 1, of the privacy element 32. B represents a sectional width, on a first section perpendicular to the driver backplane 1, of the opening where the privacy element 32 is disposed. The first section is parallel to an arrangement direction of the privacy element 32 and the normal element 31. C represents a sectional width, on the first section, of a pixel definition layer 2 disposed between the adjacent privacy element 32 and the normal element 31. The sectional width of the pixel definition layer 2 is a sectional width of the pixel definition layer 2 at a position flush with the surface on the side, away from the driver backplane 1, of the privacy element 32. x represents a distance, on the first section, between an edge of an end, close to the privacy element 32, of the first wiring 41 or dummy wiring 5 and an edge of an end, close to the first wiring 41 or dummy wiring 5, of the first light-emitting functional layer 322. y represents a distance, on the first section, between an edge of an end, away from the privacy element 32, of the first wiring 41 or dummy wiring 5 and an edge of an end, close to the first wiring 41 or dummy wiring 5, of the second light-emitting functional layer 312. z represents a thickness of the first wiring 41 or dummy wiring 5. θ represents a viewing angle of the normal element 31 on the first section.

θ/2 represents an included angle, on the first section, between the outermost light emitted from the normal element 31 and a normal line P perpendicular to the light-emitting surface of the normal element 31.

In some embodiments, referring to FIG. 2f, two privacy elements 32 are adjacent to each other. The adjacent two privacy elements 32 are respectively a first privacy element 32A and a second privacy element 32B, and equations for calculating a line width N of the first wiring 41 which is disposed between the first privacy element 32A and the second privacy element 32B and close to an opening where the first privacy element 32A is disposed are as follows. N=C−x−y; X=A+z−B; and y=(A+z)/tan(90°−α/2)−B. A represents a distance between a surface on a side, close to the first privacy element 32A, of the first wiring 41 and a surface on a side, away from the driver backplane 1, of the first privacy element 32A. B represents a sectional width, on a second section perpendicular to the driver backplane 1, of the opening where the first privacy element 32A is disposed. The second section is parallel to an arrangement direction of the first privacy element 32A and the second privacy element 32B. C represents a sectional width, on the second section, of a pixel definition layer 2 disposed between the adjacent first privacy element 32A and the second privacy element 32B. The sectional width of the pixel definition layer 2 is a sectional width of the pixel definition layer 2 at a position flush with the surface on the side, away from the driver backplane 1, of the first privacy element 32A. x represents a distance, on the second section, between an edge of an end, close to the first privacy element 32A, of the first wiring 41 and an edge of an end, close to the first wiring 41, of the first light-emitting functional layer 322 of the first privacy element 32A. y represents a distance, on the second section, between an edge of an end, away from the first privacy element 32A, of the first wiring 41 and an edge of an end, close to the first wiring 41, of the first light-emitting functional layer 312 of the second privacy element 32B. z represents a thickness of the first wiring 41. α represents a viewing angle of the second privacy element 32B on the second section.
α/2 represents an included angle, on the second section, between the outermost light emitted from the second privacy element 32B and a normal line P′ perpendicular to a light-emitting surface of the second privacy element 32B.

In some embodiments, the structural arrangement of the first wiring 41 and the dummy wiring 5 in FIG. 2b and the method of calculating the line widths of the first wiring 41 and the dummy wiring 5 in FIG. 2d and FIG. 2f apply to achieving the privacy display of a medium-to-large-sized display panel, such as a display panel of less than 10 inches or a display panel with a resolution of less than 300 PPI.

In some embodiments, θ ranges from 120° to 160°. Preferably, 0 is 120°.

In some embodiments, α ranges from 40° to 50°. Preferably, a is 45°.

In some embodiments, referring to FIG. 2c, FIG. 2d, FIG. 2e, and FIG. 2f, the display panel further includes a package layer 6 and a light-shielding layer 7. The package layer 6 is disposed on the side, away from the driver backplane 1, of the light-emitting device 3, and on a side, close to the driver backplane 1, of the touch line 4 and the dummy wiring 5. The package layer 6 is configured to package the light-emitting device 3. The light-shielding layer 7 is disposed on a side, away from the driver backplane 1, of the touch line 4 and the dummy wiring 5. An orthographic projection of the light-shielding layer 7 on the driver backplane 1 at least covers an orthographic projection of the first wiring 41, disposed between the orthographic projections of the adjacent privacy elements 32 on the driver backplane 1, on the driver backplane 1 and an orthographic projection of the first wiring 41 or the dummy wiring 5, disposed between the orthographic projections of the adjacent privacy element 32 and the normal element 31 on the driver backplane 1, on the driver backplane 1.

In some embodiments, an area of the orthographic projection of the light-shielding layer 7 on the driver backplane 1 is equal to an area of the orthographic projection of the first wiring 41 and/or the dummy wiring 5 on the driver backplane 1. In some embodiments, an area of the orthographic projection of the light-shielding layer 7 on the driver backplane 1 is greater than an area of the orthographic projection of the first wiring 41 and/or the dummy wiring 5 on the driver backplane 1. By providing the light-shielding layer 7, in one aspect, the light with a large viewing angle emitted by the privacy element 32 is shielded, which facilitates the realization of the privacy angle and privacy effect of the privacy element 32; in another aspect, the reflectivity of the first wiring 41 and/or the dummy wiring 5 to the ambient light is reduced, which contributes to the reduction of the visibility of the first wiring 41 and/or the dummy wiring 5.

FIG. 2h is another sectional schematic structural diagram along a section line AA in FIG. 2a. In some embodiments, referring to FIG. 2h, the light-shielding layer 7 is disposed on the side, close to the driver backplane 1, of the touch line 4 and the dummy wiring 5 and on a side, away from the driver backplane 1, of the package layer 6. With such an arrangement, the light-shielding layer 7 first absorbs the large viewing angle light emitted by the privacy element 32, and then further absorbs the large viewing angle light reflected by the touch line 4 and the dummy wiring 5, which facilitates the achievement the privacy angle and the privacy effect of the privacy element 32.

In some embodiments, the light-shielding layer is disposed on a side, close to the driver backplane, of the package layer and on a side, away from the driver backplane, of the light-emitting device (not shown in the figures). With such an arrangement, the light-shielding layer likewise absorbs the large viewing angle light emitted by the privacy element first, and then further absorbs the large viewing angle light reflected by the touch line and the dummy wiring, which facilitates the achievement of the privacy angle and privacy effect of the privacy element.

In some embodiments, the light-shielding layer 7 is made of a black organic material, such as a black resin material, a black matrix material, or the like

In some embodiments, referring to FIG. 2c, FIG. 2d, FIG. 2e, and FIG. 2f, the display panel further includes a first media layer 8 and a second media layer 9. The first media layer 8 is disposed on the side, away from the driver backplane 1, of the package layer 6 and on the side, close to the driver backplane 1, of the touch line 4 and the dummy wiring 5. The second media layer 9 is disposed on the side, away from the driver backplane 1, of the touch line 4 and the dummy wiring 5.

In some embodiments, the first dielectric layer 8 and the second dielectric layer 9 are made of an inorganic insulating material, such as silicon nitride, silicon oxide, or silicon oxynitride.

In some embodiments, referring to FIG. 2a and FIG. 2b, the display panel further includes a plurality of data lines 10. The plurality of light-emitting devices 3 are arranged in an array, and each column of light-emitting devices 3 is connected to one of the data lines 10. In the light-emitting devices 3, the privacy elements 32 and the normal elements 31 are arranged along a column direction of the array, and the privacy elements 32 and the normal elements 31 are electrically connected to the same data line 10.

In some embodiments, referring to FIG. 2a and FIG. 2b, in the array of the light-emitting devices 3, odd rows are the privacy elements 32, and even rows are the normal elements 31. The privacy elements 32 and the normal elements 31 are successively alternately arranged along the column direction of the array. In some embodiments, in the array of light-emitting devices, odd rows are the normal elements and even rows are the privacy elements.

In some embodiments, referring to FIG. 2c and FIG. 2d, the plurality of light-emitting devices 3 include a plurality of red light-emitting devices 301, a plurality of green light-emitting devices 302, and a plurality of blue light-emitting devices 303. Each of the red light-emitting devices 301 includes a red privacy element and a red normal element. Each of the green light-emitting devices 302 includes a green privacy element and a green normal element. Each of the blue light-emitting devices 303 includes a blue privacy element and a blue normal element. A slope angle Q1 of a portion of the pixel definition layer 2, wherein an opening, where the green privacy element is disposed, is formed in the portion is greater than a slope angle Q2 of a portion of the pixel definition layer 2, wherein an opening, where the red privacy element is disposed, is formed in the portion, and the slope angle Q2 of the portion of the pixel definition layer 2, wherein the opening, where the red privacy element is disposed, is formed in the portion is greater than a slope angle Q3 of a portion of the pixel definition layer 2, wherein an opening, where the blue privacy element is disposed, is formed in the portion. The vision of the human eye is sensitive to green light, therefore, by defining the slope angles of the portions of the pixel definition layer 2 as described above, wherein the openings where the privacy elements of different colors are respectively disposed are respectively formed within the portions, the privacy display of the display panel achieves a better effect.

In some embodiments, referring to FIG. 2a and FIG. 2b, the plurality of light-emitting devices 3 include a plurality of red light-emitting devices 301, a plurality of green light-emitting devices 302, and a plurality of blue light-emitting devices 303. Each of the red light-emitting devices 301 includes a red privacy element and a red normal element. Each of the green light-emitting devices 302 includes a green privacy element and a green normal element. Each of the blue light-emitting devices 303 includes a blue privacy element and a blue normal element. A ratio of an area of a continuous closed shape formed by an orthographic of a dummy wiring 5 and a first wiring 41, which correspond to the green privacy element of the green light-emitting device 302, on the driver backplane 1 to an area of an orthographic projection of the green privacy element on the driver backplane 1 is M1. A ratio of an area of a continuous closed shape formed by an orthographic projection of a dummy wiring 5 and a first wiring 41, which correspond to the red privacy element of the red light-emitting device 301, on the driver backplane 1 to an area of an orthographic projection of the red privacy element on the driver backplane 1 is M2. A ratio of an area of a continuous closed shape formed by an orthographic projection of a dummy wiring 5 and a first wiring 41, which correspond to the blue privacy element of the blue light-emitting device 303, on the driver backplane 1 to an area of an orthographic projection of the blue privacy element on the driver backplane 1 is M3. M1 is at least greater than one of M2 and M3. In some embodiments, M1>M2≥M3, or M1>M2>M3. The vision of the human eye has different levels of sensitivity to light of different colors, therefore, by arranging the dummy wirings 5 and the first wirings 41 of the regions where the privacy elements of different colors are disposed as described above, the privacy display of the display panel achieves a better effect.

In some embodiments, portions of the pixel definition layer 2 have a same slope angle, wherein openings, where the red normal element, the green normal element, and the blue normal element respectively are disposed, are respectively formed in the portions.

In some embodiments, referring to FIG. 2a and FIG. 2b, the driver backplane 1 further includes a plurality of pixel circuits. Each of the light-emitting devices 3 is electrically connected to one of the pixel circuits. Each of the pixel circuits includes a driver transistor 30, which is electrically connected to the normal element 31 and the privacy element 32 of one light-emitting device 3. That is, the normal element 31 and the privacy element 32 of one light-emitting device 3 are connected to the same driver transistor 3. By enabling one of the pixel circuits to drive the normal element 31 and the privacy element 32 of one of the light-emitting devices 3, the circuit space and circuit cost are saved, and the difficulty in preparing the pixel circuit is reduced.

In some embodiments, the pixel circuit further includes a switching transistor. The normal element 31 and the privacy element 32 are connected to different switching transistors, such that the turning on of the normal element 31 and the privacy element 32 is controlled respectively.

In some embodiments, referring to FIG. 2a and FIG. 2b, a first electrode 304 of the driver transistors 30 in the pixel circuit is connected to the second anode 311 of the normal element 31 and the first anode 321 of the privacy element 32 of the light-emitting device 3.

In some embodiments, the driver transistor 30 further includes an active layer 305, a first gate insulation layer 308, a gate electrode 306, and a second electrode 307. The first electrode 304 and the second electrode 307 are disposed in the same layer. The driver backplane 1 further includes a substrate 11, a buffer layer 12, an intermediate dielectric layer 13, and a planarization layer 14. The buffer layer 12, the active layer 305, the first gate insulation layer 308, the gate 306, the intermediate dielectric layer 13, the first electrode 304, the second electrode 307, and the planarization layer 14 are successively stacked on a side of the substrate 11. The second anode 311 and the first anode 321 are disposed on a side, away from the substrate 11, of the planarization layer 14. The first electrode 304 of the driver transistor 30 is connected to the second anode 311 and the first anode 321 through a via formed in the planarization layer 14.

In the display panel according to some embodiments of the present disclosure, the line width of the first wiring line is greater than the line width of the second wiring line, and the second wiring line is arranged as the touch line as usual in the spacing region between the openings where the light-emitting device are disposed. The first wiring line, in one aspect, is served as the touch line and exerts a touch control function of the touch line, and in another aspect, is used to form a shield for the light-exiting region at the periphery edges of the opening where the privacy element is disposed, such that the area of the light-exiting region of the opening where the privacy element is disposed is reduced, and thus the viewing angle of the privacy element is restricted to the preset privacy viewing angle range, and the privacy display of the display panel in some privacy scenarios is achieved.

Some embodiments of the present disclosure further provide a method for driving a display panel. In the case that the display panel is in a normal state, a driver backplane drives normal elements and privacy elements in light-emitting devices to emit light. In the case that the display panel is in a privacy state, the driver backplane drives the privacy elements in the light-emitting devices to emit light.

Specifically, in the case that the display panel is in the normal state (e.g., the normal state indicates that the display panel is displayed within a viewing angle of 120°), a pixel circuit in the driver backplane drives the normal elements and the privacy elements in the light-emitting devices to emit light, such that a normal display of the display panel is achieved. In the case that the display panel is in the privacy state (e.g., the privacy state indicates that the display panel is displayed within a viewing angle of 45°), the pixel circuit in the driver backplane drives only the privacy elements in the light-emitting devices to emit light, such that a privacy display of the display panel is achieved.

Some embodiments of the present disclosure further provide a display device, the display device includes the display panel as described above.

By employing the display panel as described above, in one aspect, a normal display (i.e., a large viewing angle range display, e.g., a large viewing angle range from 120° to) 160° of the display panel is achieved; in another aspect, a privacy display (i.e., a privacy viewing angle range display, e.g., a privacy viewing angle range from 40° to) 50° of the display panel is achieved.

The display device according to the embodiments of the present disclosure is an OLED panel, an OLED TV, an OLED billboard, a monitor, a smartphone, a navigator, and any other product or component having a display function.

It should be understood that described above are merely exemplary embodiments of the present disclosure, and are not intended to limit the present disclosure. Therefore, for those skilled in the art, any modifications, equivalent substitutions, improvements, and the like made within the spirit and principles of the present disclosure shall be included in the protection scope of the present disclosure.

1. A display panel, comprising: a driver backplane, a pixel definition layer, a plurality of light-emitting devices, and a touch line; wherein
the pixel definition layer is disposed on a side of the driver backplane, and a plurality of openings are formed in the pixel definition layer;
each of the light-emitting devices comprises a normal element and at least one privacy element, wherein the privacy element and the normal element are respectively disposed in different openings of the plurality of openings;
the touch line is disposed on a side, away from the driver backplane, of the light-emitting device;
the touch line comprises a first wiring and a second wiring, wherein an orthographic projection of the first wiring on the driver backplane falls on a periphery of an orthographic projection of an opening, where the privacy element is disposed, on the driver backplane;
a distance between an orthographic projection of the second wiring on the driver backplane and the orthographic projection of the opening, where the privacy element is disposed, on the driver backplane is greater than a distance between the orthographic projection of the first wiring on the driver backplane and the orthographic projection of the opening, where the privacy element is disposed, on the driver backplane; and
a line width of at least a partial region of the first wiring is greater than a line width of the second wiring.

2. The display panel according to claim 1, wherein the orthographic projection of the first wiring on the driver backplane forms a continuous closed shape.

3. The display panel according to claim 1, wherein
the orthographic projection of the first wiring on the driver backplane is discontinuous in a region between orthographic projections of some of the privacy elements and the normal elements adjacent to each other on the driver backplane; and
the display panel further comprises a dummy wiring disposed on the side, away from the driver backplane, of the light-emitting device; wherein
an orthographic projection of the dummy wiring on the driver backplane falls between the orthographic projections of some of the privacy elements and the normal elements adjacent to each other on the driver backplane, and the orthographic projection of the dummy wiring on the driver backplane falls in a discontinuity region of the orthographic projection of the first wiring on the driver backplane;
a distance between the orthographic projection of the dummy wiring on the driver backplane and the orthographic projection of the opening, where the privacy element is disposed, on the driver backplane is less than the distance between the orthographic projection of the second wiring on the driver backplane and the orthographic projection of the opening, where the privacy element is disposed, on the driver backplane;
a line width of the dummy wiring is greater than the line width of the second wiring; and
the dummy wiring and the first wiring are insulated from each other, and the orthographic projections of the dummy wiring and the first wiring on the driver backplane form a continuous closed shape.

4. The display panel according to claim 3, wherein
the privacy element comprises a first anode, a first light-emitting functional layer, and a first cathode; and
the normal element comprises a second anode, a second light-emitting functional layer, and a second cathode; wherein
the first anode, the first light-emitting functional layer, and the first cathode are successively stacked along a direction away from the driver backplane;
the second anode, the second light-emitting functional layer, and the second cathode are successively stacked along the direction away from the driver backplane; and
the orthographic projections of the first wiring and the dummy wiring on the driver backplane are not overlapped with an orthographic projection of the second light-emitting functional layer on the driver backplane.

5. The display panel according to claim 4, wherein the orthographic projections of the first wiring and the dummy wiring on the driver backplane are overlapped with peripheral edges of an orthographic projection of the first light-emitting functional layer on the driver backplane.

6. The display panel according to claim 4, wherein the orthographic projections of the first wiring and the dummy wiring on the driver backplane are not overlapped with an orthographic projection of the first light-emitting functional layer on the driver backplane.

7. The display panel according to claim 5, wherein the privacy element is adjacent to the normal element, and equations for calculating a width M of the first wiring or the dummy wiring line disposed between the privacy element and the normal that are adjacent to each other are as follows:
$$\begin{matrix}M = C + x - y ; \\ x = B - A - z ; and \\ y = ( A + z ) / tan ( 90 ° - θ / 2 ) - B ;\end{matrix}$$
wherein
A represents a distance between a surface of a side, close to the privacy element, of the first wiring or the dummy wiring and a surface of a side, away from the driver backplane, of the privacy element;
B represents a sectional width, on a first section perpendicular to the driver backplane, of the opening where the privacy element is disposed, wherein the first section is parallel to an arrangement direction of the privacy element and the normal element;
C represents a sectional width, on the first section, of the pixel definition layer disposed between the privacy element and the normal element adjacent to each other, wherein the sectional width of the pixel definition layer refers to a sectional width of the pixel definition layer at a position flush with the surface of the side, away from the driver backplane, of the privacy element;
x represents a distance, on the first section, between an edge of an end, close to the privacy element, of the first wiring or the dummy wiring and an edge of an end, close to the first wiring or the dummy wiring, of the first light-emitting feature layer;
y represents a distance, on the first section, between an edge of an end, away from the privacy element, of the first wiring or the dummy wiring and an edge of an end, close to the first wiring or the dummy wiring, of the second light-emitting functional layer;
z represents a thickness of the first wiring or the dummy wiring; and
θ represents a viewing angle of the normal element on the first section.

8. The display panel according to claim 5, wherein two of the privacy elements are adjacent to each other, and the adjacent two privacy elements are respectively a first privacy element and a second privacy element; and
equations for calculating a line width N of the first wiring disposed between the first privacy element and the second privacy element and close to an opening where the first privacy element is disposed are as follows:
$$\begin{matrix}N = C + x - y ; \\ x = B - A - z ; and \\ y = ( A + z ) / tan ( 90 ° - α / 2 ) - B ;\end{matrix}$$
wherein
A represents a distance between a surface of a side, close to the first privacy element, of the first wiring and a surface of a side, away from the driver backplane, of the first privacy element;
B represents a sectional width, on a second section perpendicular to the driver backplane, of the opening where the first privacy element is disposed, wherein the second section is parallel to an arrangement direction of the first privacy element and the second privacy element;
C represents a sectional width, on the second section, of the pixel definition layer disposed between the first privacy element and the second privacy element adjacent to each other, wherein the sectional width of the pixel definition layer refers to a sectional width of the pixel definition layer at a position flush with the surface of the side, away from the driver backplane, of the first privacy element;
x represents a distance, on the second section, between an edge of an end, close to the first privacy element, of the first wiring and an edge of an end, close to the first wiring, of the first light-emitting feature layer of the first privacy element;
y represents a distance, on the second section, between an edge of an end, away from the first privacy element, of the first wiring and an edge of an end, close to the first wiring, of the first light-emitting functional layer of the second privacy element;
z represents a thickness of the first wiring; and
α represents a viewing angle of the second privacy element on the second section.

9. The display panel according to claim 6, wherein the privacy element is adjacent to the normal element; and
equations for calculating a width M of the first wiring or the dummy wiring disposed between the privacy element and the normal element adjacent to each other are as follows:
$$\begin{matrix}M = C - x - y ; \\ x = A + z - B ; and \\ y = ( A + z ) / tan ( 90 ° - θ / 2 ) - B ;\end{matrix}$$
wherein
A represents a distance between a surface of a side, close to the privacy element, of the first wiring or the dummy wiring and a surface of a side, away from the driver backplane, of the privacy element;
B represents a sectional width, on a first section perpendicular to the driver backplane, of the opening where the privacy element is disposed, wherein the first section is parallel to an arrangement direction of the privacy element and the normal element;
C represents a sectional width, on the first section, of the pixel definition layer disposed between the privacy element and the normal element adjacent to each other, wherein the sectional width of the pixel definition layer refers to a sectional width of the pixel definition layer at a position flush with the surface of the side, away from the driver backplane, of the privacy element;
x represents a distance, on the first section, between an edge of an end, close to the privacy element, of the first wiring or the dummy wiring and an edge of an end, close to the first wiring or the dummy wiring, of the first light-emitting feature layer;
y represents a distance, on the first section, between an edge of an end, away from the privacy element, of the first wiring or the dummy wiring and an edge of an end, close to the first wiring or the dummy wiring, of the second light-emitting functional layer;
z represents a thickness of the first wiring or the dummy wiring; and
θ represents a viewing angle of the normal element on the first section.

10. The display panel according to claim 6, wherein two of the privacy elements are adjacent to each other, and the adjacent two privacy elements are respectively a first privacy element and a second privacy element; and
equations calculating a line width N of the first wiring disposed between the first privacy element and the second privacy element and close to an opening where the first privacy element is disposed are as follows:
$$\begin{matrix}N = C - x - y ; \\ x = A + z - B ; and \\ y = ( A + z ) / tan ( 90 ° - α / 2 ) - B ;\end{matrix}$$
wherein
A represents a distance between a surface of a side, close to the first privacy element, of the first wiring and a surface of a side, away from the driver backplane, of the first privacy element;
B represents a sectional width, on a second section perpendicular to the driver backplane, of the opening where the first privacy element is disposed, wherein the second section is parallel to an arrangement direction of the first privacy element and the second privacy element;
C represents a sectional width, on the second section, of the pixel definition layer disposed between the first privacy element and the second privacy element adjacent to each other, wherein the sectional width of the pixel definition layer refers to a sectional width of the pixel definition layer at a position flush with the surface of the side, away from the driver backplane, of the first privacy element;
x represents a distance, on the second section, between an edge of an end, close to the first privacy element, of the first wiring and an edge of an end, close to the first wiring, of the first light-emitting feature layer of the first privacy element;
y represents a distance, on the second section, between an edge of an end, away from the first privacy element, of the first wiring and an edge of an end, close to the first wiring, of the first light-emitting functional layer of the second privacy element;
z represents a thickness of the first wiring; and
α represents a viewing angle of the second privacy element on the second section.

11. The display panel according to claim 7, wherein 0 ranges from 120° to 160°.

12. The display panel according to claim 8, wherein a ranges from 40° to 100°.

13. The display panel according to claim 3, further comprising: a package layer and a light-shielding layer; wherein
the package layer is disposed on the side, away from the driver backplane, of the light-emitting device and on a side, close to the driver backplane, of the touch line and the dummy wiring, and the package layer is configured to package the light-emitting device;
the light-shielding layer is disposed on a side, away from the driver backplane, of the touch line and the dummy wiring; or
the light-shielding layer is disposed on the side, close to the driver backplane, of the touch line and the dummy wiring and on a side, away from the driver backplane, of the package layer; or
the light-shielding layer is disposed on a side, close to the driver backplane, of the package layer and on the side, away from the driver backplane, of the light-emitting device; and
an orthographic projection of the light-shielding layer on the driver backplane at least covers the orthographic projection of the first wiring on the driver backplane disposed between the orthographic projections of the adjacent privacy elements on the driver backplane and the orthographic projection of the first wiring or the dummy wiring on the driver backplane disposed between the orthographic projections of the adjacent privacy element and the normal element on the driver backplane.

14. (canceled)

15. The display panel according to claim 1, further comprising a plurality of data lines; wherein
the plurality of light-emitting devices are arranged in an array;
each column of the light-emitting devices is connected to one of the data lines; and
in the light-emitting devices, the privacy elements and the normal elements are arranged along a column direction of the array, and the privacy elements and the normal elements are electrically connected to the same data line of the plurality of data lines.

16. The display panel according to claim 15, wherein
in the array of light-emitting devices, odd rows are the privacy elements, and even rows are the normal elements; or
in the array of light-emitting devices, odd rows are the normal elements, and even rows are the privacy elements; and
the privacy elements and the normal elements are successively alternately arranged along the column direction of the array.

17. The display panel according to claim 1, wherein the plurality of light-emitting devices comprise a plurality of red light-emitting devices, a plurality of green light-emitting devices, and a plurality of blue light-emitting devices; wherein
each of the red light-emitting devices comprises a red privacy element and a red normal element;
each of the green light-emitting devices comprises a green privacy element and a green normal element; and
each of the blue light-emitting devices comprises a blue privacy element and a blue normal element;
wherein a slope angle of a portion of the pixel definition layer, wherein an opening, where the green privacy element is disposed, is formed in the portion is greater than a slope angle of a portion of the pixel definition layer, wherein an opening, where the red privacy element is disposed, is formed in the portion, and the slope angle of the portion of the pixel definition layer, wherein the opening, where the red privacy element is disposed, is formed in the portion is greater than a slope angle of a portion of the pixel definition layer, wherein an opening, where the blue privacy element is disposed, is formed in the portion.

18. The display panel according to claim 17, wherein portions of the pixel definition layer have a same slope angle, wherein openings, where the red normal element, the green normal element, and the blue normal element respectively are disposed, are respectively formed in the portions.

19. The display panel according to claim 1, wherein the driver backplane comprises a plurality of pixel circuits; wherein
each of the light-emitting devices is electrically connected to one of the pixel circuits; and
each of the pixel circuits comprises a driver transistor, wherein the driver transistor is electrically connected to the normal element and the privacy element of one of the light-emitting devices.

20. A display device, comprising: a display panel wherein
the display panel comprises: a driver backplane, a pixel definition layer, a plurality of light-emitting devices, and a touch line; wherein
the pixel definition layer is disposed on a side of the driver backplane, and a plurality of openings are formed in the pixel definition layer;
each of the light-emitting devices comprises a normal element and at least one privacy element, wherein the privacy element and the normal element are respectively disposed in different openings of the plurality of openings;
the touch line is disposed on a side, away from the driver backplane, of the light-emitting device;
the touch line comprises a first wiring and a second wiring, wherein an orthographic projection of the first wiring on the driver backplane falls on a periphery of an orthographic projection of an opening, where the privacy element is disposed, on the driver backplane;
a distance between an orthographic projection of the second wiring on the driver backplane and the orthographic projection of the opening, where the privacy element is disposed, on the driver backplane is greater than a distance between the orthographic projection of the first wiring on the driver backplane and the orthographic projection of the opening, where the privacy element is disposed, on the driver backplane; and
a line width of at least a partial region of the first wiring is greater than a line width of the second wiring.

21. A method for driving a display panel, comprising:
driving a normal element and a privacy element of a light-emitting device to emit light by a driver backplane in a case where the display panel is in a normal state; or
driving the privacy element of the light-emitting device to emit light by the driver backplane in a case where the display panel is in a privacy state.
